(19) United States
(12) Patent Application Publication
(10) Pub. No.: US 2026/0282222 A1
(43) Pub. Date: Sep. 17, 2026

(54) WIRING BOARD

(71) Applicant: KYOCERA CORPORATION, Kyoto-shi, Kyoto (JP)

(72) Inventor: Junpei KAWASE, Kyoto-shi (JP)

(73) Assignee: KYOCERA CORPORATION, Kyoto-shi, Kyoto (JP)

(21) Appl. No.: 19/166,111

(22) PCT Filed: Mar. 21, 2024
(86) PCT No.: PCT/JP2024/011014

§ 371 Date: Sep. 17, 2025

(30) Foreign Application Priority Data
Mar. 24, 2023 (JP) 2023-048831

(51) Int. Cl. H05K 1/11; H05K 1/02

(52) U.S. Cl. CPC H05K 1/111; H05K 1/0216; H05K 2201/09227; H05K 2201/09427

(57) ABSTRACT

To reduce the possibility of being affected by electromagnetic noise in signal transmission. A wiring board of an aspect of the present disclosure includes a substrate including a first surface, a second surface, and a lateral surface, a plurality of first connection terminals located on the first surface, a plurality of first external terminals located on the second surface, a plurality of first wiring conductors located inside the substrate and configured to connect the first connection terminals and the first external terminals, a first conductor connected to each of the plurality of first wiring conductors and extending from an inside of the substrate to the lateral surface, a first metal body located inside the substrate independently of the first wiring conductors, and a second conductor connected to the first metal body and extending from the inside of the substrate to the lateral surface.

### TECHNICAL FIELD

The present disclosure relates to a wiring board.

### BACKGROUND OF INVENTION

For example, Patent Document 1 discloses a wiring board including a plurality of conductors independent of each other as auxiliary conductors for electrolytic plating.

### CITATION LIST

### Patent Literature

Patent Document 1: JP 2011-29424 A

### SUMMARY

An aspect of the present disclosure implements a wiring board capable of reducing the possibility of being affected by electromagnetic noise in signal transmission.

### SOLUTION TO PROBLEM

A wiring board according to an aspect of the present disclosure includes: a substrate including a first surface; a plurality of first connection terminals located on the first surface; a plurality of first external terminals located on a second surface; a plurality of first wiring conductors located inside the substrate and configured to connect the first connection terminals and the first external terminals; a first conductor connected to each of the plurality of first wiring conductors and extending from an inside of the substrate to a lateral surface; a first metal body located inside the substrate independently of the first wiring conductors; and a second conductor connected to the first metal body and extending from the inside of the substrate to the lateral surface.

### BRIEF DESCRIPTION OF THE DRAWINGS

FIG. 1 is a top view of a wiring board according to a first embodiment of the present disclosure.

FIG. 2 is a cross-sectional view taken along line II-II illustrated in FIG. 1.

FIG. 3 is a plan view illustrating a second wiring layer included in the wiring board.

FIG. 4 is a plan view illustrating a third wiring layer included in the wiring board.

FIG. 5 is a perspective view of a lower surface of a substrate included in the wiring board when viewed from above.

FIG. 6 is a cross-sectional view taken along line VI-VI illustrated in FIG. 3.

FIG. 7 is a top view of a wiring board according to a second embodiment of the present disclosure.

FIG. 8 is a cross-sectional view taken along the line VIII-VIII illustrated in FIG. 7.

FIG. 9 is a plan view illustrating a second wiring layer included in the wiring board.

FIG. 10 is a plan view illustrating a third wiring layer included in the wiring board.

FIG. 11 is a perspective view of a lower surface of a substrate included in the wiring board when viewed from above.

### DESCRIPTION OF EMBODIMENTS

When an auxiliary conductor for electrolytic plating functions as an antenna, signal transmission through a wiring board may be affected by electromagnetic noise. According to an aspect of the present disclosure, the possibility of being affected by electromagnetic noise in signal transmission can be reduced.

### First Embodiment

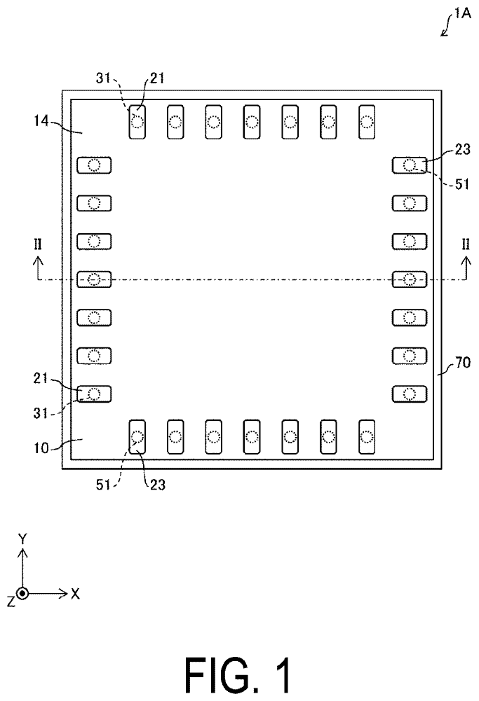

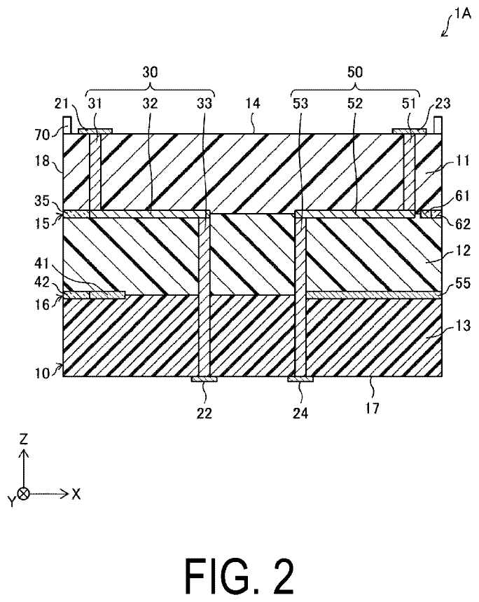

An embodiment of the present disclosure is described below in detail. FIG. 1 is a top view of a wiring board 1A in the present embodiment. FIG. 2 is a cross-sectional view taken along line II-II illustrated in FIG. 1. In the following description, an X axis direction, a Y axis direction, and a Z axis direction illustrated in FIG. 1 are described as a left-right direction, a front-rear direction, and an up-down direction, respectively. In addition, in FIG. 1, a +X axis direction, a −X axis direction, a +Z axis direction, and a −Z axis direction are described as a right direction, a left direction, an up direction, and a down direction, respectively.

As illustrated in FIGS. 1 and 2, the wiring board 1A includes a substrate 10, a plurality of first connection terminals 21, a plurality of first external terminals 22, a plurality of first wiring conductors 30, a plurality of first conductors 35, a first metal body 41, a plurality of second conductors 42, a plurality of second connection terminals 23, a plurality of second external terminals 24, a plurality of second wiring conductors 50, a plurality of third conductors 55, a second metal body 61, a plurality of fourth conductors 62, and a frame body 70.

The substrate 10 has a thickness in the up-down direction. In the following description, the Z-axis direction may be referred to as a thickness direction. The substrate 10 may include a plurality of insulation layers layered in the thickness direction. As illustrated in FIG. 2, the substrate 10 in the present embodiment is configured by layering a first insulation layer 11, a second insulation layer 12, and a third insulation layer 13 from the upper direction to the down direction. The first insulation layer 11, the second insulation layer 12, and the third insulation layer 13 are each made of an insulation material. As the insulation material, ceramic such as alumina and aluminum nitride, resin, and the like can be used.

An upper surface of the first insulation layer 11 is an upper surface 14 of the substrate 10 as a first surface. The upper surface 14 of the substrate 10 may be a flat surface perpendicular to the thickness direction. The upper surface 14 of the substrate 10 functions as a first wiring layer. The upper surface 14 of the substrate 10 is provided with the plurality of first connection terminals 21 and the plurality of second connection terminals 23. In other words, the first connection terminal 21 and the second connection terminal 23 are located on the upper surface 14 of the substrate 10. The first connection terminals 21 and the second connection terminals 23 are terminals for electrically connecting to electrodes of electronic components (not illustrated) mounted on the wiring board 1A. The first connection terminal 21 and the second connection terminal 23 may have a plating layer on the upper surface thereof.

As illustrated in FIG. 1, some of the first connection terminals 21 are located on the upper surface 14 of the substrate 10 so as to be arranged at equal intervals along the front-rear direction, and the other first connection terminals 21 are located on the upper surface 14 of the substrate 10 so as to be arranged at equal intervals along the left-right direction. In the following description, the front-rear direction may be referred to as a first direction and the left-right direction may be referred to as a second direction.

The first connection terminal 21 and the second connection terminal 23 may be provided along the outer edge of the upper surface 14 of the substrate 10. For example, a case where the electronic components mounted on the wiring board 1A are image sensors is described. In the present embodiment, a plurality of light receiving elements may be arranged as pixels in a central portion of the image sensor. In addition, a plurality of connection terminals with the wiring board may be arranged side by side at an outer edge portion of the image sensor. In this case, the first connection terminal 21 and the second connection terminal 23 are arranged side by side along the outer edge of the upper surface 14 of the substrate 10, and thus the connection distance between the first connection terminal 21/the second connection terminal 23 and the terminals on the image sensor side is shortened. This reduces the resistance of the wiring for connection. In addition, when a connection is made by wire bonding, the occurrence of a connection failure of the bonding wire is suppressed.

As illustrated in FIG. 2, a region between the first insulation layer 11 and the second insulation layer 12 functions as a second wiring layer 15, and a region between the second insulation layer 12 and the third insulation layer 13 functions as a third wiring layer 16.

A lower surface of the third insulation layer 13 is a lower surface 17 of the substrate 10 as a second surface. The lower surface 17 of the substrate 10 may be a flat surface perpendicular to the thickness direction. The lower surface 17 of the substrate 10 is a surface opposite to the upper surface 14 of the substrate 10. The lower surface 17 is opposite to the upper surface 14.

The lower surface 17 of the substrate 10 functions as a fourth wiring layer. The lower surface 17 of the substrate 10 is provided with the plurality of first external terminals 22 and the plurality of second external terminals 24. In other words, the first external terminal 22 and the second external terminal 24 are located on the lower surface 17 of the substrate 10. The first external terminal 22 and the second external terminal 24 are terminals for electrically connecting to electrodes of an external device. The electrode of the external device may be, for example, a mounting electrode of a printed circuit board.

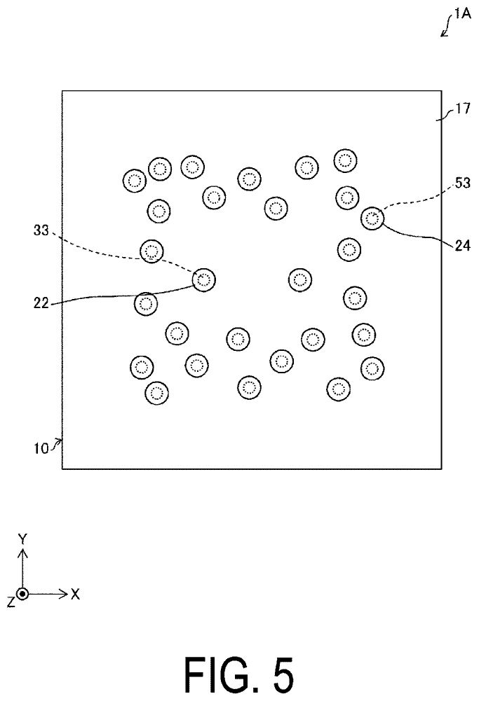

The first external terminal 22 and the second external terminal 24 may be located away from the outer edge of the lower surface 17 of the substrate 10 as illustrated in FIG. 5 to be described below. When the first external terminal 22 and the second external terminal 24 are located at the outer edge of the lower surface 17 of the substrate 10, the first external terminal 22 and the second external terminal 24 may come into contact with some external constituent member and may be short-circuited. On the other hand, when the first external terminal 22 and the second external terminal 24 are located away from the outer edge of the lower surface 17 of the substrate 10, the first external terminal 22 and the second external terminal 24 are covered with the substrate 10, and thus the possibility of the occurrence of a short circuit can be reduced.

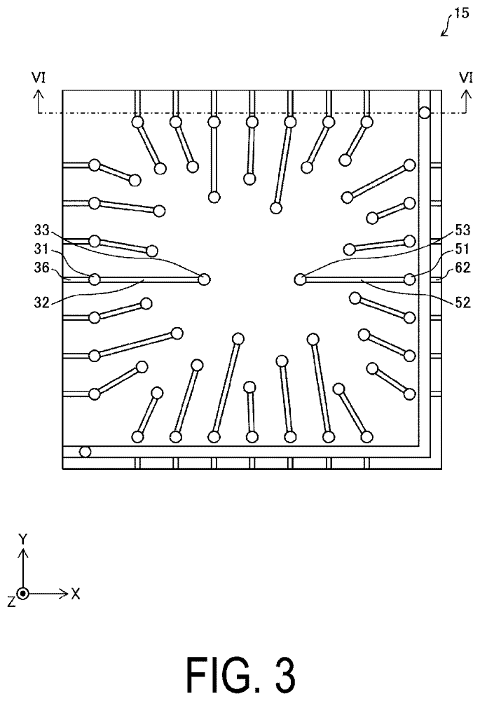

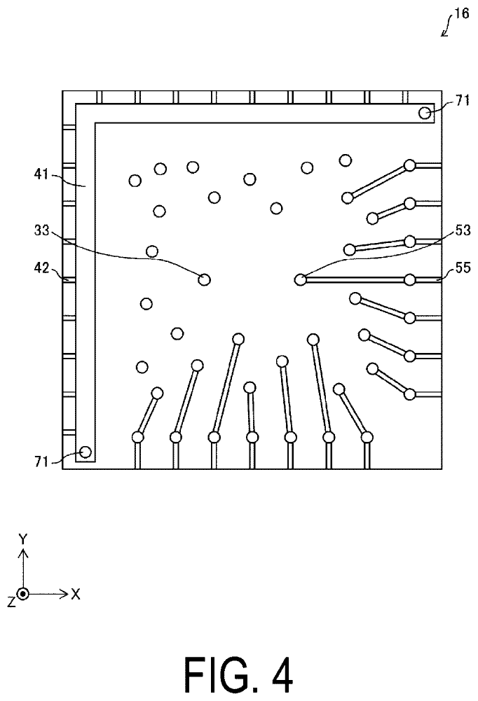

As illustrated in FIG. 2, each of the plurality of first wiring conductors 30 connects the first connection terminal 21 and the first external terminal 22. In other words, each of the plurality of first connection terminals 21 is connected to any of the plurality of first external terminals 22 by the first wiring conductor 30. The connection between the first connection terminal 21 and the first external terminal 22 by the first wiring conductor 30 is described with reference to FIGS. 1 to 5. FIG. 3 is a plan view illustrating the second wiring layer 15. FIG. 4 is a plan view illustrating the third wiring layer 16. FIG. 5 is a perspective view of the lower surface 17 of the substrate 10 when viewed from above.

As illustrated in FIG. 2, the first wiring conductor 30 is located inside the substrate 10. The first wiring conductor 30 has electrical conductivity. The first wiring conductor 30 may be made of a metal having a high melting point, such as molybdenum or tungsten. This reduces the possibility of melting of the first wiring conductors 30 when the substrate 10 is made of ceramic and the wiring board 1A is manufactured by heating the ceramic. The first wiring conductor 30 includes a first via conductor 31, a first interlayer conductor 32, and a second via conductor 33.

As illustrated in FIG. 2, the first via conductor 31 extends in a direction perpendicular to the upper surface 14 of the substrate 10. In other words, the first via conductor 31 extends in the thickness direction. The first via conductor 31 may have, for example, a cylindrical shape extending in the thickness direction. The first via conductor 31 is provided inside the first insulation layer 11. As illustrated in FIG. 2, an upper end of the first via conductor 31 is connected to the first connection terminal 21, and a lower end of the first via conductor 31 is connected to the first interlayer conductor 32. With this configuration, the first via conductor 31 electrically connects the first connection terminal 21 and the first interlayer conductor 32.

As illustrated in FIGS. 2 and 3, the first interlayer conductor 32 may be provided in the second wiring layer 15. In this case, the first interlayer conductor 32 extends in a direction parallel to the upper surface 14 of the substrate 10. One end portion of the first interlayer conductor 32 is connected to the first via conductor 31, and the other end portion thereof is connected to the second via conductor 33. With this configuration, the first interlayer conductor 32 electrically connects the first via conductor 31 and the second via conductor 33.

As illustrated in FIG. 2, the second via conductor 33 extends in the direction perpendicular to the upper surface 14 of the substrate 10. In other words, the second via conductor 33 extends in the thickness direction. The second via conductor 33 may have, for example, a cylindrical shape extending in the thickness direction. The second via conductor 33 is provided inside the second insulation layer 12 and inside the third insulation layer 13. As illustrated in FIGS. 2 and 5, an upper end of the second via conductor 33 is connected to the first interlayer conductor 32, and a lower end of the second via conductor 33 is connected to the first external terminal 22. With this configuration, the second via conductor 33 electrically connects the first interlayer conductor 32 and the first external terminal 22.

The first wiring conductor 30 includes the first via conductor 31, the first interlayer conductor 32, and the second via conductor 33 having the above configuration, and thus electrically connects the first connection terminal 21 and the first external terminal 22.

The first conductor 35 is a conductor used as an auxiliary conductor when a plating layer is formed on the first connection terminal 21 by electrolytic plating. The first conductor 35 is connected to the first wiring conductor 30 and extends from the inside of the substrate 10 to a lateral surface 18. The lateral surface 18 is a surface extending from the upper surface 14 toward the lower surface 17. The first conductor 35 has electrical conductivity. The first conductor 35 may be made of the same material as the material constituting the first wiring conductor 30, or may be made of a material different from the material constituting the first wiring conductor 30. As illustrated in FIGS. 2 and 3, the first conductor 35 may be provided in the second wiring layer 15. In this case, one end portion of the first conductor 35 is connected to the first via conductor 31 of the first wiring conductor 30, and the other end portion thereof is exposed from the lateral surface 18 of the substrate 10. A width of the first conductor 35 may be smaller than a width of the first via conductor 31. The first conductors 35 are not used for electrical connection in the use of the wiring board 1A.

The first metal body 41 is located inside the substrate 10 independently of the first wiring conductor 30. The term “independent” means that the first metal body 41 and the first wiring conductor 30 are not electrically connected to each other. The first metal body 41 has electrical conductivity. The first metal body 41 may be made of the same material as the material constituting the first wiring conductor 30, or may be made of a material different from the material constituting the first wiring conductor 30. As illustrated in FIGS. 2 and 4, the first metal body 41 may be provided in the third wiring layer 16. In the example illustrated in FIG. 4, the first metal body 41 has an L-shape including a portion extending along the front-rear direction as a first portion and a portion extending along the left-right direction in plan view. In the example illustrated in FIG. 4, the first metal body 41 has the portion extending in the front-rear direction at the outer edge portion on a left side of the third wiring layer 16, and the portion extending in the left-right direction at the outer edge portion on an upper side of the third wiring layer 16. The first metal body 41 can be used for electrical connection such as ground connection.

The second conductor 42 is connected to the first metal body 41 and extends from the inside of the substrate 10 to the lateral surface 18. The second conductor 42 has electrical conductivity. The second conductor 42 may be made of the same material as the material constituting the first wiring conductor 30, or may be made of a material different from the material constituting the first wiring conductor 30. As illustrated in FIGS. 2 and 4, the second conductor 42 may be provided in the third wiring layer 16. In this case, one end portion of the second conductor 42 is connected to the first metal body 41, and the other end portion thereof is exposed from the lateral surface 18 of the substrate 10. A width of the second conductor 42 may be smaller than a width of the first metal body 41. In the present embodiment, the second conductors 42 are not used for electrical connection in the use of the wiring board 1A.

As illustrated in FIG. 2, each of the plurality of second wiring conductors 50 connects the second connection terminal 23 and the second external terminal 24. In other words, each of the plurality of second connection terminals 23 is connected to any of the plurality of second external terminals 24 by the second wiring conductor 50. The connection between the second connection terminal 23 and the second external terminal 24 by the second wiring conductor 50 is described with reference to FIGS. 1 to 5.

As illustrated in FIG. 2, the second wiring conductor 50 is located inside the substrate 10. The second wiring conductor 50 has electrical conductivity. A material constituting the second wiring conductor 50 may be the same as the material constituting the first wiring conductor 30, or may be different from the material constituting the first wiring conductor 30.

The second wiring conductor 50 includes a third via conductor 51, a second interlayer conductor 52, and a fourth via conductor 53.

The third via conductor 51 extends in the direction perpendicular to the upper surface 14 of the substrate 10. In other words, the third via conductor 51 extends in the thickness direction. The third via conductor 51 may have the same shape as the first via conductor 31. The third via conductor 51 is provided inside the first insulation layer 11. An upper end of the third via conductor 51 is connected to the second connection terminal 23, and a lower end of the third via conductor 51 is connected to the second interlayer conductor 52. With this configuration, the third via conductor 51 electrically connects the second connection terminal 23 and the second interlayer conductor 52.

As illustrated in FIGS. 2 and 3, the second interlayer conductor 52 may be provided in the second wiring layer 15. In this case, the second interlayer conductor 52 extends in the direction parallel to the upper surface 14 of the substrate 10. One end portion of the second interlayer conductor 52 is connected to the third via conductor 51, and the other end portion thereof is connected to the fourth via conductor 53. With this configuration, the second interlayer conductor 52 electrically connects the third via conductor 51 and the fourth via conductor 53.

The fourth via conductor 53 extends in the direction perpendicular to the upper surface 14 of the substrate 10. In other words, the fourth via conductor 53 extends in the thickness direction. The fourth via conductor 53 may have the same shape as the second via conductor 33. The fourth via conductor 53 is provided inside the second insulation layer 12 and inside the third insulation layer 13. As illustrated in FIGS. 2 and 5, an upper end of the fourth via conductor 53 is connected to the second interlayer conductor 52, and a lower end of the fourth via conductor 53 is connected to the second external terminal 24. With this configuration, the fourth via conductor 53 electrically connects the second interlayer conductor 52 and the second external terminal 24.

The second wiring conductor 50 includes the third via conductor 51, the second interlayer conductor 52, and the fourth via conductor 53 having the above configuration, and thus electrically connects the second connection terminal 23 and the second external terminal 24.

The third conductor 55 is connected to the second wiring conductor 50 and extends from the inside of the substrate 10 to the lateral surface 18. The third conductor 55 has electrical conductivity. The third conductor 55 may be made of the same material as the material constituting the first wiring conductor 30, or may be made of a material different from the material constituting the first wiring conductor 30. As illustrated in FIGS. 2 and 4, the third conductor 55 may be provided in the third wiring layer 16. In this case, one end portion of the third conductor 55 is connected to the fourth via conductor 53 of the second wiring conductor 50, and the other end portion thereof is exposed from the lateral surface 18 of the substrate 10. An end surface of the third conductor 55 exposed at the lateral surface 18 of the substrate 10 may be flush with the lateral surface 18 of the substrate 10.

The second metal body 61 is located inside the substrate 10 independently of the first wiring conductor 30 and the first metal body 41. The second metal body 61 has electrical conductivity. The second metal body 61 may be made of the same material as the material constituting the first wiring conductor 30, or may be made of a material different from the material constituting the first wiring conductor 30. As illustrated in FIGS. 2 and 3, the second metal body 61 may be provided in the second wiring layer 15. In the example illustrated in FIG. 3, the second metal body 61 has an L-shape including a portion extending along the front-rear direction and a portion extending along the left-right direction as a second portion in plan view. In the example illustrated in FIG. 3, the second metal body 61 has the portion extending in the front-rear direction at the outer edge portion on a right side of the third wiring layer 16, and the portion extending along the left-right direction at the outer edge portion on a lower side of the third wiring layer 16.

The fourth conductor 62 is connected to the second metal body 61 and extends from the inside of the substrate 10 to the lateral surface 18. The fourth conductor 62 has electrical conductivity. The fourth conductor 62 may be made of the same material as the material constituting the first wiring conductor 30, or may be made of a material different from the material constituting the first wiring conductor 30. As illustrated in FIGS. 2 and 3, the fourth conductor 62 may be provided in the second wiring layer 15. In this case, one end portion of the fourth conductor 62 is connected to the second metal body 61, and the other end portion thereof is exposed from the lateral surface 18 of the substrate 10. An end surface of the fourth conductor 62 exposed at the lateral surface 18 of the substrate 10 may be flush with the lateral surface 18 of the substrate 10. The fourth conductor 62 may be located on the same line as the first conductor 35. More specifically, the first conductor 35 may be located on an extension line of an imaginary line along which the fourth conductor 62 extends from the second metal body 61. In the example illustrated in FIG. 2, the fourth conductor 62 and the first conductor 35 are located on the same straight line extending in the X direction.

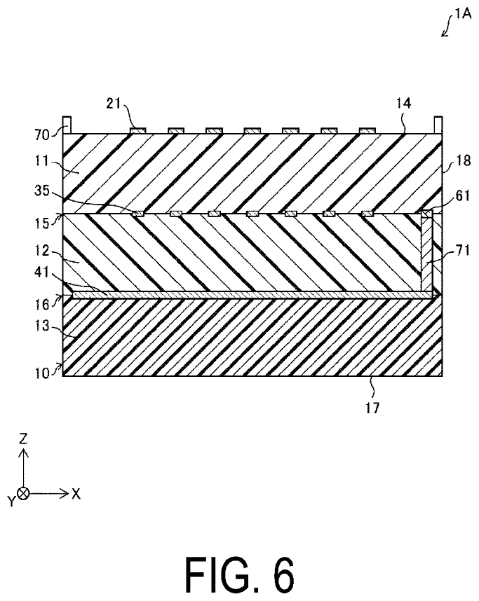

FIG. 6 is a cross-sectional view taken along line VI-VI illustrated in FIG. 3. As illustrated in FIG. 6, the first metal body 41 and the second metal body 61 are electrically connected to each other via connection conductors 71. The connection conductor 71 includes a conductor extending in the thickness direction of the substrate 10. The connection conductor 71 may have the same shape as the first via conductor 31. In the wiring board 1A in the present embodiment, the connection conductors 71 are formed at two positions, that is, the upper right and the lower left of the substrate 10 when viewed from above in plan view; however, but the present disclosure is not limited thereto. Only one connection conductor 71 may be provided, or three of more connection conductors 71 may be provided. In the wiring board 1A of an aspect of the present disclosure, the connection conductor 71 may extend from the second wiring layer 15 to the lower surface 17 of the substrate 10, and the connection conductors 71 may be exposed from the lower surface 17. Moreover, for example, the connection conductor 71 exposed from the lower surface 17 may be connected to a metal index mark. In this case, the index mark may be used to check the presence or absence of an electric leakage to the first metal body 41 and/or the second metal body 61 in the wiring board 1A. In the present embodiment, the index mark may include various configurations that are not used for electrical connection in a normal use state and are visually recognizable in appearance, and may be, for example, a pattern used for authenticity determination of whether a product is genuine by appearance inspection, confirmation of an attachment direction, and the like.

The frame body 70 may be located at the outer edge portion of the upper surface 14 of the substrate 10. The frame body 70 defines a region where electronic components are mounted on the wiring board 1A. The frame body 70 may be provided to overlap at least a part of the first conductor 35 in perspective plan view from the X-axis direction.

Operations and Effects As described above, the wiring board 1A is provided with the first conductors 35 used as auxiliary conductors when a plating layer is formed on the first connection terminals 21 by electrolytic plating. The first conductors 35 are formed at regular intervals in the first direction and the second direction in correspondence with the arrangement of the first connection terminals 21. Therefore, when the distance between the first conductors 35 is the same as the wavelength of a signal such as a high-frequency signal, the first conductors 35 may receive an unnecessary signal. In this case, electromagnetic noise may occur in signal transmission performed between the first connection terminal 21 and the first external terminal 22 and signal transmission performed between the second connection terminal 23 and the second external terminal 24.

On the other hand, the wiring board 1A includes the first metal body 41 to which the second conductors 42 extending from the inside of the substrate 10 to the lateral surface 18 are connected. Thus, the first metal body 41 functions as an electromagnetic shield that absorbs electromagnetic noise. As a result, compared to a wiring board in the related art, the possibility of being affected by electromagnetic noise can be reduced in signal transmission performed between the first connection terminal 21 and the first external terminal 22 and signal transmission performed between the second connection terminal 23 and the second external terminal 24. Therefore, the necessity of noise countermeasures such as attaching an electromagnetic shield to the outside of the substrate 10 can be reduced.

In order to further absorb electromagnetic noise by the first metal body 41, increasing the size of the first metal body 41 is effective to bring the potential of the first metal body 41 close to the ground potential. In the wiring board 1A of the present embodiment, as illustrated in FIGS. 3 and 4, the first metal body 41 may have a band shape thicker than the second metal body 61. This makes it easier for the first metal body 41 to absorb electromagnetic noise, and thus the influence of electromagnetic noise can be further reduced. In the wiring board 1A in the present disclosure, the first metal body 41 can be formed in any shape as long as the first metal body 41 is formed in a region of the third wiring layer excluding the second via conductors 33, the fourth via conductors 53, and the third conductors 55. Therefore, for example, the first metal body 41 may be formed in all of the regions except for the second via conductors 33, the fourth via conductors 53, and the third conductors 55 in the third wiring layer. This allows the first metal body 41 to be larger, and thus the first metal body 41 more easily absorbs electromagnetic noise.

In the wiring board 1A in the present embodiment, a part of the plurality of first connection terminals 21 may be located side by side along the front-rear direction (first direction) in plan view, and the first metal body 41 may have the first portion extending along the front-rear direction.

In the wiring board 1A in the present embodiment, the substrate 10 may include a plurality of insulation layers, that is, the first insulation layer 11, the second insulation layer 12, and the third insulation layer 13 that are layered in the thickness direction. This allows the portion between the first insulation layer 11 and the second insulation layer 12 and the portion between the second insulation layer 12 and the third insulation layer 13 to function as the second wiring layer 15 and the third wiring layer 16, respectively. This allows the conductors such as the first metal body 41 and the first interlayer conductor 32 to be disposed in the second wiring layer 15 or the third wiring layer 16. As a result, the position of each conductor in the thickness direction can be limited, and in particular, the positional accuracy of each conductor in the thickness direction can be improved.

The substrate 10 of the wiring board 1A does not necessarily have to be constituted by three insulation layers. In the wiring board 1A of an aspect of the present disclosure, the substrate 10 may be constituted by two insulation layers. In this case, the first metal body 41 may be provided on the upper surface 14 of the substrate 10. When the first metal body 41 is provided on the upper surface 14 of the substrate, the first metal body 41 may be covered with the same material as the material constituting the substrate 10.

In the wiring board 1A in the present embodiment, the first metal body 41 and the second conductor 42 need not be located at the same height in the thickness direction. For example, in a wiring board of an aspect of the present disclosure, the second conductors 42 connected by via conductors extending in the thickness direction may be formed in a layer different from the layer in which the first metal body 41 is formed. However, since the first metal body 41 and the second conductor 42 are located at the same height in the thickness direction, the thickness of the substrate 10 can be reduced as compared with the case where the first metal body 41 and the second conductor 42 are located at different heights in the thickness direction.

Moreover, since the first metal body 41 and the second conductor 42 are located at the same height in the thickness direction, the length of the second conductor 42 in the thickness direction can be shortened. As a result, since the length in the direction perpendicular to the thickness direction may be mainly controlled when the second conductor 42 is formed, the length of the second conductor 42 in the direction perpendicular to the thickness direction is easily controlled to be able to reduce the influence of reception of electromagnetic noise.

In the wiring board 1A in the present embodiment, the first conductors 35 and the second conductors 42 need not be located at different heights in the thickness direction.

However, when the first conductor 35 and the second conductor 42 are located at the same height in the thickness direction, the first conductor 35 and the second conductor 42 need be designed not to interfere with each other. On the other hand, when the first conductor 35 and the second conductor 42 are located at different heights in the thickness direction, since the first conductor 35 and the second conductor 42 do not interfere with each other, the degree of freedom in design can be improved.

The wiring board 1A of an aspect of the present disclosure may not necessarily include the plurality of second connection terminals 23, the plurality of second external terminals 24, the plurality of second wiring conductors 50, the plurality of third conductors 55, the second metal body 61, and the plurality of fourth conductors 62, but the wiring board 1A can be designed more flexibly by including these members.

In the wiring board 1A of an aspect of the present disclosure, the first metal body 41 and the second metal body 61 need not be located at different heights in the thickness direction.

However, since the first metal body 41 and the second metal body 61 are located at different heights in the thickness direction, electromagnetic noise not absorbable by the first metal body 41 is easily absorbed by the second metal body 61.

In the wiring board 1A of an aspect of the present disclosure, the first metal body 41 and the second metal body 61 need not be connected to each other via the connection conductors 71. However, since the first metal body 41 and the second metal body 61 are connected to each other via the connection conductors 71, the metal body can be increased in size, and thus the potential of the metal body is stabilized. This can improve the shielding performance of electromagnetic noise.

In the wiring board 1A of an aspect of the present disclosure, the second conductors 42 and the third conductors 55 need not be located at the same height in the thickness direction.

However, since the second conductor 42 and the third conductor 55 are located at the same height in the thickness direction, the thickness of the substrate 10 can be reduced.

In the wiring board 1A of an aspect of the present disclosure, the end surfaces of the first conductor 35 and the second conductor 42 need not be exposed at the lateral surface 18 of the substrate 10. However, since the end surfaces of the first conductor 35 and the second conductor 42 are exposed at the lateral surface 18 of the substrate 10, the first connection terminal 21 and the second connection terminal 23 can be used as conductors for plating when a large number of first connection terminals 21 and second connection terminals 23 are obtained.

In the wiring board 1A of an aspect of the present disclosure, the first interlayer conductor 32 may be located between layers different from a layer in which the first metal body 41 is located, and at least a part of the first interlayer conductor 32 may overlap the first metal body 41 in perspective plan view. This allows the distance between the first metal body 41 and the ground to be adjusted by a depth, and thus the electromagnetic shielding function of the first metal body 41 is easily controlled.

In the wiring board 1A of an aspect of the present disclosure, a part of the substrate 10 needs not be located between adjacent first conductors 35. However, since a part of the substrate 10 is located between adjacent first conductors 35, the fixability between the layers constituting the substrate 10 can be improved.

In the wiring board 1A, when the substrate 10 is made of a material having a lower thermal conductivity than the first metal body 41 and the second conductors 42, heat can be dissipated from the inside of the wiring board 1A to the outside via the first metal body 41 and the second conductors 42. In the wiring board 1A, the frame body 70 may be provided to overlap at least a part of the first conductors 35 in perspective plan view. This increases the thickness of the wiring board 1A, improving heat dissipation.

The present embodiment has a configuration in which the first external terminal 22 and the second external terminal 24 are provided on the lower surface 17 of the substrate 10; however, the present disclosure is not limited thereto. A wiring board of an aspect of the present disclosure may have a configuration in which the first external terminal 22 and the second external terminal 24 are provided on the lateral surface 18 of the substrate 10.

### Second Embodiment

Another embodiment of the present disclosure is described below. For convenience of description, members having the same functions as those of the members described in the above embodiment are denoted by the same reference signs, and description thereof is not repeated.

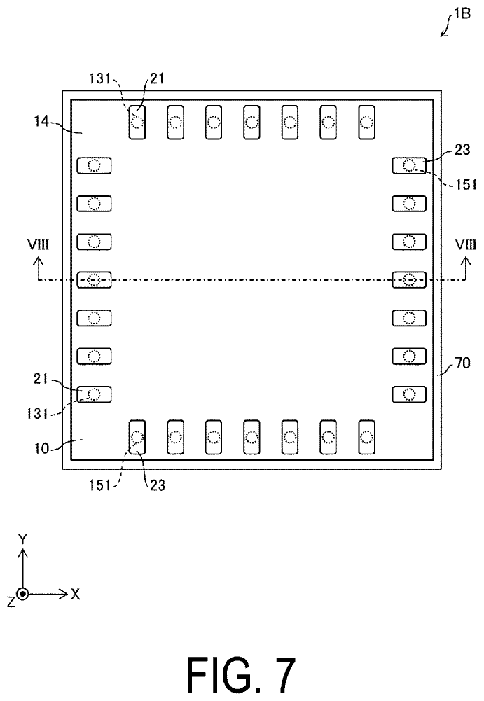

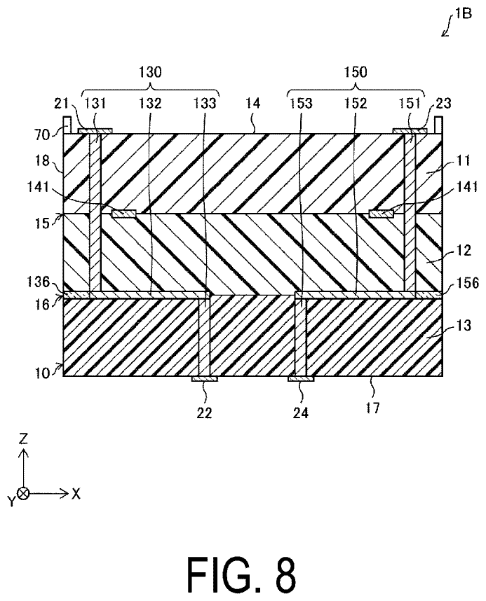

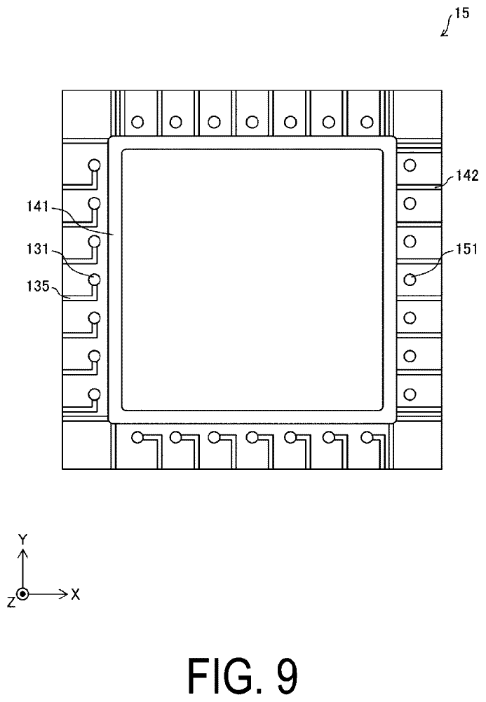

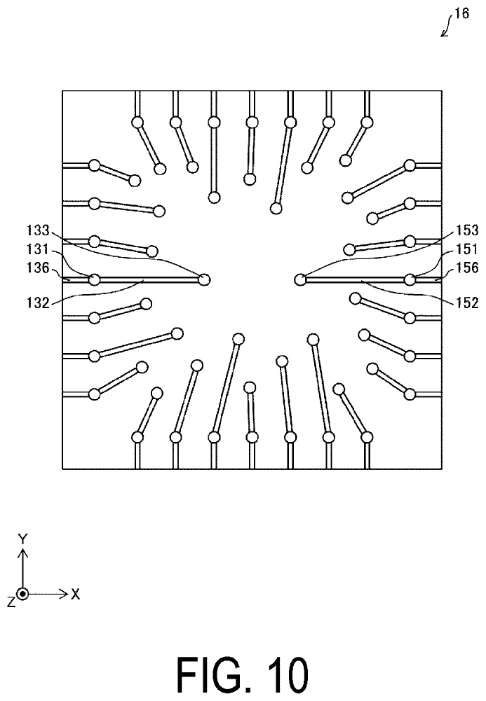

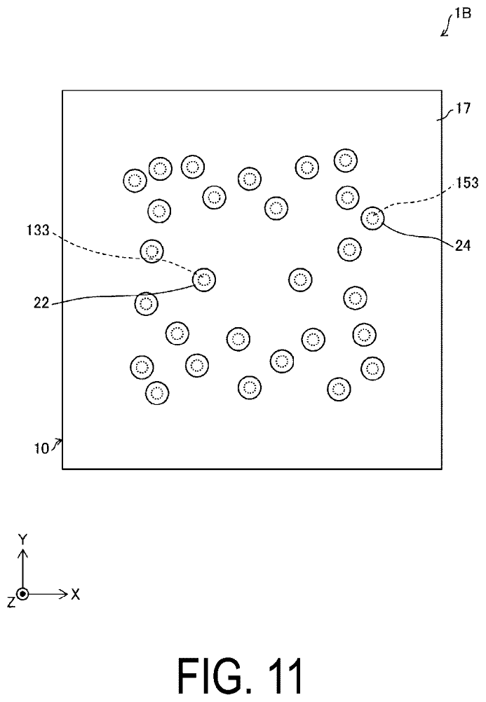

FIG. 7 is a top view of a wiring board 1B in the present embodiment. FIG. 8 is a cross-sectional view taken along line VIII-VIII illustrated in FIG. 1. FIG. 9 is a plan view illustrating a second wiring layer 15. FIG. 10 is a plan view illustrating a third wiring layer 16. FIG. 11 is a perspective view of a lower surface 17 of a substrate 10 when viewed from above. is a plan view and a perspective view of the lower surface 17 when viewed from above.

As illustrated in FIGS. 7 to 11, the wiring board 1B includes a plurality of first connection terminals 21, a plurality of first external terminals 22, a plurality of first wiring conductors 130, a plurality of first conductors 135, a plurality of fifth conductors 136, a plurality of second connection terminals 23, a plurality of second external terminals 24, a plurality of second wiring conductors 150, a plurality of sixth conductors 156, a metal body 141 (first metal body), a plurality of second conductors 142, and a frame body 70.

As illustrated in FIG. 8, each of the plurality of first wiring conductors 130 connects the first connection terminal 21 and the first external terminal 22. The connection between the first connection terminal 21 and the first external terminal 22 by the first wiring conductor 130 is described with reference to FIGS. 7 to 11.

As illustrated in FIG. 8, the first wiring conductor 130 is located inside the substrate 10. The first wiring conductor 130 has electrical conductivity. The first wiring conductor 130 may be made of, for example, a metal having a high melting point, such as molybdenum or tungsten. The first wiring conductor 130 includes a first via conductor 131, a first interlayer conductor 132, and a second via conductor 133.

As illustrated in FIG. 8, the first via conductors 131 extend in a direction perpendicular to an upper surface 14 of the substrate 10. The first via conductor 131 is provided inside a first insulation layer 11 and inside a second insulation layer 12. As illustrated in FIG. 8, an upper end of the first via conductor 131 is connected to the first connection terminal 21, and a lower end of the first via conductor 31 is connected to the first interlayer conductor 132.

As illustrated in FIGS. 8 and 10, the first interlayer conductor 132 may be provided in the third wiring layer 16. In this case, the first interlayer conductor 132 extends in a direction parallel to the upper surface 14 of the substrate 10. One end portion of the first interlayer conductor 132 is connected to the first via conductor 131, and the other end portion thereof is connected to the second via conductor 133.

As illustrated in FIG. 8, the second via conductors 133 extend in the direction perpendicular to the upper surface 14 of the substrate 10. The second via conductors 133 is provided inside a third insulation layer 13. As illustrated in FIGS. 8 and 11, an upper end of the second via conductor 133 is connected to the first interlayer conductor 132, and a lower end of the second via conductor 133 is connected to the first external terminal 22.

The first wiring conductor 130 includes the first via conductor 131, the first interlayer conductor 132, and the second via conductor 133 having the above configuration, and thus electrically connects the first connection terminal 21 and the first external terminal 22.

The first conductor 135 is a conductor used as an auxiliary conductor when a plating layer is formed on the first connection terminal 21 by electrolytic plating. As illustrated in FIG. 9, the first conductor 135 is connected to the first wiring conductor 130, has an L-shape, and extends from the inside of the substrate 10 to a lateral surface 18. The first conductor 135 has electrical conductivity. The first conductor 135 may be made of the same material as the material constituting the first wiring conductor 130, or may be made of a material different from the material constituting the first wiring conductor 130. As illustrated in FIGS. 8 and 9, the first conductor 135 may be provided in the second wiring layer 15. In this case, one end portion of the first conductor 135 is connected to the first via conductor 131 of the first wiring conductor 130, and the other end portion thereof is exposed from the lateral surface 18 of the substrate 10. A width of the first conductor 135 may be smaller than a width of the first via conductor 131. The first conductors 135 are not used for electrical connection in the use of the wiring board 1B.

The fifth conductor 136 is a conductor used as an auxiliary conductor when a plating layer is formed on the first connection terminal 21 by electrolytic plating. The fifth conductor 136 is connected to the first wiring conductor 130 and extends from the inside of the substrate 10 to the lateral surface 18. The fifth conductor 136 has electrical conductivity. The fifth conductor 136 may be made of the same material as the material constituting the first wiring conductor 130, or may be made of a material different from the material constituting the first wiring conductor 130. As illustrated in FIGS. 8 and 10, the fifth conductor 136 may be provided in the third wiring layer 16. In this case, one end portion of the fifth conductor 136 is connected to the first via conductor 131 of the first wiring conductor 130, and the other end portion thereof is exposed from the lateral surface 18 of the substrate 10. A width of the fifth conductor 136 may be smaller than a width of the first via conductor 131. The fifth conductors 136 are not used for electrical connection in the use of the wiring board 1B.

As illustrated in FIG. 8, each of the plurality of second wiring conductors 150 connects the second connection terminal 23 and the second external terminal 24. The connection between the second connection terminal 23 and the second external terminal 24 by the second wiring conductor 150 is described with reference to FIGS. 7 to 11.

As illustrated in FIG. 8, the second wiring conductor 150 is located inside the substrate 10. The second wiring conductor 150 has electrical conductivity. The material constituting the second wiring conductor 150 may be the same as the material constituting the first wiring conductor 130, or may be different from the material constituting the first wiring conductor 130. The second wiring conductor 150 includes a third via conductor 151, a second interlayer conductor 152, and a fourth via conductor 153.

The third via conductors 151 extend in the direction perpendicular to the upper surface 14 of the substrate 10. The third via conductor 151 is provided inside the first insulation layer 11 and inside the second insulation layer 12. An upper end of the third via conductor 151 is connected to the second connection terminal 23, and a lower end of the third via conductor 151 is connected to the second interlayer conductor 152.

As illustrated in FIGS. 8 and 10, the second interlayer conductor 152 may be provided in the third wiring layer 16. In this case, the second interlayer conductor 152 extends in the direction parallel to the upper surface 14 of the substrate 10. One end portion of the second interlayer conductor 152 is connected to the third via conductor 151, and the other end portion thereof is connected to the fourth via conductor 153.

The fourth via conductor 153 extends in the direction perpendicular to the upper surface 14 of the substrate 10. The fourth via conductor 153 is provided inside the third insulation layer 13. As illustrated in FIGS. 8 and 11, an upper end of the fourth via conductor 153 is connected to the second interlayer conductor 152, and a lower end of the fourth via conductor 153 is connected to the second external terminal 24.

The second wiring conductor 150 includes the third via conductor 151, the second interlayer conductor 152, and the fourth via conductor 153 having the above configuration, and thus electrically connects the second connection terminal 23 and the second external terminal 24.

The sixth conductor 156 is connected to the second wiring conductor 150 and extends from the inside of the substrate 10 to the lateral surface 18. The sixth conductor 156 has electrical conductivity. The sixth conductor 156 may be made of the same material as the material constituting the first wiring conductor 130, or may be made of a material different from the material constituting the first wiring conductor 130. As illustrated in FIGS. 8 and 10, the sixth conductor 156 may be provided in the third wiring layer 16. In this case, one end portion of the sixth conductor 156 is connected to the third via conductor 151 of the second wiring conductor 150, and the other end portion thereof is exposed from the lateral surface 18 of the substrate 10.

The metal body 141 is located inside the substrate 10 independently of the first wiring conductor 130. The term “independent” means that the metal body 141 and the first wiring conductor 130 are not electrically connected to each other. The metal body 141 has electrical conductivity. The metal body 141 may be made of the same material as the material constituting the first wiring conductor 130, or may be made of a material different from the material constituting the first wiring conductor 130. As illustrated in FIGS. 8 and 9, the metal body 141 may be provided in the second wiring layer 15. In the example illustrated in FIG. 9, the metal body 141 is formed in a rectangular frame shape having a space therein. However, the metal body 141 is not limited to this shape, and may be formed in a circular frame shape, or may be formed as a single rectangular metal plate having no space therein, for example.

The second conductor 142 is connected to the metal body 141 and extends from the inside of the substrate 10 to the lateral surface 18. The second conductor 142 has electrical conductivity. The second conductor 142 may be made of the same material as the material constituting the first wiring conductor 130, or may be made of a material different from the material constituting the first wiring conductor 130. As illustrated in FIG. 9, the second conductor 142 may be provided in the second wiring layer 15. In this case, one end portion of the second conductor 142 is connected to the metal body 141, and the other end portion thereof is exposed from the lateral surface 18 of the substrate 10. A width of the second conductor 142 may be smaller than a width of the metal body 141. In the present embodiment, the second conductors 142 are not used for electrical connection in the use of the wiring board 1B.

As described above, the wiring board 1B is provided with the first conductors 135 used as auxiliary conductors when a plating layer is formed on the first connection terminals 21 by electrolytic plating. The first conductors 135 are formed at regular intervals in correspondence with the arrangement of the first connection terminals 21. Therefore, when the distance between the first conductors 35 is the same as the wavelength of a signal such as a high-frequency signal, the first conductor 135 may receive an unnecessary signal. In this case, electromagnetic noise may occur in signal transmission performed between the first connection terminal 21 and the first external terminal 22 and signal transmission performed between the second connection terminal 23 and the second external terminal 24.

On the other hand, the wiring board 1B includes the metal body 141 to which the second conductors 142 extending from the inside of the substrate 10 to the lateral surface 18 are connected. Thus, the metal body 141 functions as an electromagnetic shield that absorbs electromagnetic noise. As a result, compared to a wiring board in the related art, the possibility of being affected by electromagnetic noise can be reduced in signal transmission performed between the first connection terminal 21 and the first external terminal 22 and signal transmission performed between the second connection terminal 23 and the second external terminal 24. Therefore, the necessity of noise countermeasures such as attaching an electromagnetic shield to the outside of the substrate 10 can be reduced.

The wiring board 1B is configured to have only the metal body 141 as a metal body for reducing the possibility of being affected by electromagnetic noise. This reduces the thickness of the substrate 10 and eliminates the need for the connection conductors 71 in the first embodiment, compared to the case where the substrate 10 includes a plurality of metal bodies located in different layers as in the wiring board 1A in the first embodiment.

The invention according to the present disclosure has been described above based on various drawings and example. However, the invention according to the present disclosure is not limited to each embodiment described above. That is, the invention according to the present disclosure can be modified in various ways within the scope described in the present disclosure, and embodiments obtained by combining technical means disclosed in the different embodiments as appropriate are also included in the technical scope of the invention according to the present disclosure. That is, it is noted that a person skilled in the art can easily make various variations or modifications based on the present disclosure. It is also noted that these variations or modifications are included in the scope of the present disclosure.

### Conclusion

A wiring board according to a first aspect of the present disclosure includes a substrate including a first surface, a second surface opposite to the first surface, and a lateral surface extending from the first surface toward the second surface, a plurality of first connection terminals located on the first surface, a plurality of first external terminals located on the second surface, a plurality of first wiring conductors located inside the substrate and configured to connect the first connection terminals and the first external terminals, a first conductor connected to each of the plurality of first wiring conductors and extending from an inside of the substrate to the lateral surface, a first metal body located inside the substrate independently of the first wiring conductors, and a second conductor connected to the first metal body and extending from the inside of the substrate to the lateral surface.

In the wiring board according to a second aspect of the present disclosure, in the first aspect, at least a part of the plurality of first connection terminals may be located side by side along a first direction in plan view, and the first metal body may include a first portion extending along the first direction.

In the wiring board according to a third aspect of the present disclosure, in the first or second aspect, a direction perpendicular to the first surface may be a thickness direction, and the substrate may include a plurality of insulation layers layered in the thickness direction.

In the wiring board according to a fourth aspect of the present disclosure, in any one of the first to third aspects, the direction perpendicular to the first surface may be the thickness direction, and the first metal body and the second conductor may be located at the same height in the thickness direction.

In the wiring board according to a fifth aspect of the present disclosure, in any one of the first to fourth aspects, the direction perpendicular to the first surface may be the thickness direction, and the first conductor and the second conductor may be located at different heights in the thickness direction.

In the wiring board according to a sixth aspect of the present disclosure, in any one of the first to fifth aspects, the second surface may be a surface opposite to the first surface, and the first external terminals may be located away from an outer edge of the second surface.

The wiring board according to a seventh aspect of the present disclosure may further include, in any one of the first to sixth aspects, a plurality of second connection terminals located on the first surface, a plurality of second external terminals located on the second surface, a plurality of second wiring conductors located inside the substrate and configured to connect the second connection terminals and the second external terminals, a third conductor connected to each of the plurality of second wiring conductors and extending from the inside of the substrate to the lateral surface, a second metal body located inside the substrate independently of the first wiring conductors and the first metal body, and a fourth conductor connected to the second metal body and extending from the inside of the substrate to the lateral surface.

In the wiring board according to an eighth aspect of the present disclosure, in the seventh aspect, at least a part of the plurality of second connection terminals may be located along a second direction in plan view, and the second metal body may include a second portion extending along the second direction.

In the wiring board according to a ninth aspect of the present disclosure, in the seventh or eighth aspect, the direction perpendicular to the first surface may be the thickness direction, and the first metal body and the second metal body may be located at different heights in the thickness direction.

In the wiring board according to a tenth aspect of the present disclosure, in any one of the seventh to ninth aspects, the first metal body and the second metal body may be connected to each other via a connection conductor including a conductor extending in a thickness direction of the substrate.

In the wiring board according to an eleventh aspect of the present disclosure, in any one of the seventh to tenth aspects, the direction perpendicular to the first surface may be the thickness direction, and the second conductor and the third conductor may be located at the same height in the thickness direction.

In the wiring board according to a twelfth aspect of the present disclosure, in any one of the first to eleventh aspects, end surfaces of the first conductor and the second conductor may be exposed at the lateral surface.

In the wiring board according to a thirteenth aspect of the present disclosure, in the third aspect, the first wiring conductor may include a via conductor extending in the direction perpendicular to the first surface and an interlayer conductor extending in a direction parallel to the first surface, the interlayer conductor may be located between layers different from a layer in which the first metal body is located, and at least a part of the interlayer conductor may overlap the first metal body in perspective plan view.

In the wiring board according to a fourteenth aspect of the present disclosure, in any one of the first to thirteenth aspects, the first metal body may have a band shape thicker than the second conductor.

In the wiring board according to a fifteenth aspect of the present disclosure, in any one of the first to fourteenth aspects, a part of the substrate may be located between adjacent first conductors.

In the wiring board according to a sixteenth aspect of the present disclosure, in any one of the first to fifteenth aspects, the substrate may include a frame body on the first surface, and the frame body may overlap at least a part of the first conductor in perspective plan view.

In the wiring board according to a seventeenth aspect of the present disclosure, in any one of the first to sixteenth aspects, the first connection terminal may include a plating layer.

### REFERENCE SIGNS

1A, 1B Wiring board
10 Substrate
11 First insulation layer
12 Second insulation layer
13 Third insulation layer
21 First connection terminal
22 First external terminal
23 Second connection terminal
24 Second external terminal
30, 130 First wiring conductor
31, 131 First via conductor
32, 132 First interlayer conductor
33, 133 Second via conductor
35, 135 First conductor
41 First metal body
42, 142 Second conductor
50, 150 Second wiring conductor
51, 151 Third via conductor
52, 152 Second interlayer conductor
53, 153 Fourth via conductor
55 Third conductor
61 Second metal body
62 Fourth conductor
70 Frame body
71 Connection conductor
141 Metal body (first metal body)

1. A wiring board comprising:
a substrate comprising a first surface, a second surface opposite to the first surface, and a lateral surface extending from the first surface toward the second surface;
a plurality of first connection terminals located on the first surface;
a plurality of first external terminals located on the second surface;
a plurality of first wiring conductors located inside the substrate and configured to connect the first connection terminals and the first external terminals;
a first conductor connected to each of the plurality of first wiring conductors and extending from an inside of the substrate to the lateral surface;
a first metal body located inside the substrate independently of the first wiring conductors; and
a second conductor connected to the first metal body and extending from the inside of the substrate to the lateral surface.

2. The wiring board according to claim 1, wherein at least a part of the plurality of first connection terminals is located side by side along a first direction in plan view, and
the first metal body comprises a first portion extending along the first direction.

3. The wiring board according to claim 1, wherein a direction perpendicular to the first surface is a thickness direction, and
the substrate comprises a plurality of insulation layers layered in the thickness direction.

4. The wiring board according to any one of claim 1, wherein a direction perpendicular to the first surface is a thickness direction, and
the first metal body and the second conductor are located at the same height in the thickness direction.

5. The wiring board according to any one of claim 1, wherein a direction perpendicular to the first surface is a thickness direction, and
the first conductor and the second conductor are located at different heights in the thickness direction.

6. The wiring board according to claim 1, wherein the first external terminals are located away from an outer edge of the second surface.

7. The wiring board according to claim 1, further comprising:
a plurality of second connection terminals located on the first surface;
a plurality of second external terminals located on the second surface;
a plurality of second wiring conductors located inside the substrate and configured to connect the second connection terminals and the second external terminals;
a third conductor connected to each of the plurality of second wiring conductors and extending from the inside of the substrate to the lateral surface;
a second metal body located inside the substrate independently of the first wiring conductors and the first metal body; and
a fourth conductor connected to the second metal body and extending from the inside of the substrate to the lateral surface.

8. The wiring board according to claim 7, wherein at least a part of the plurality of second connection terminals is located along a second direction in plan view, and
the second metal body comprises a second portion extending along the second direction.

9. The wiring board according to claim 7, wherein a direction perpendicular to the first surface is a thickness direction, and
the first metal body and the second metal body are located at different heights in the thickness direction.

10. The wiring board according to claim 7, wherein the first metal body and the second metal body are connected to each other via a connection conductor comprising a conductor extending in a thickness direction of the substrate.

11. The wiring board according to claim 7, wherein a direction perpendicular to the first surface is a thickness direction, and
the second conductor and the third conductor are located at the same height in the thickness direction.

12. The wiring board according to any one of claim 1, wherein end surfaces of the first conductor and the second conductor are exposed at the lateral surface.

13. The wiring board according to claim 3, wherein the first wiring conductor comprises a via conductor extending in the direction perpendicular to the first surface and an interlayer conductor extending in a direction parallel to the first surface,
the interlayer conductor is located between layers different from a layer in which the first metal body is located, and at least a part of the interlayer conductor overlaps the first metal body in perspective plan view.

14. The wiring board according to claim 1, wherein the first metal body has a band shape thicker than the second conductor.

15. The wiring board according to claim 1, wherein a part of the substrate is located between adjacent first conductors.

16. The wiring board according to claim 1, wherein the substrate comprises a frame body on the first surface, and
the frame body overlaps at least a part of the first conductor in perspective plan view.

17. The wiring board according to claim 1, wherein the first connection terminal comprises a plating layer.
